(19) United States
(12) Patent Application Publication
(10) Pub. No.: US 2009/0189791 A1
(43) Pub. Date: Jul. 30, 2009

(54) FONT OR KEYSTROKE BIOMETRICS

(76) Inventors: Michael D. Brinton, New York, NY (US); Gregory P. Manning, New York, NY (US); Antonio Papageorgiou, New York, NY (US)

Correspondence Address: DEAN P. ALDERUCCI, CANTOR FITZGERALD, L.P., 110 EAST 59TH STREET (6TH FLOOR), NEW YORK, NY, 10022, US

(21) Appl. No.: 12/361,930

(22) Filed: Jan. 29, 2009

Related U.S. Application Data
(60) Provisional application No. 61/024,415, filed on Jan. 29, 2008.

(51) Int. Cl. H03M 11/00; G06K 9/00

(52) U.S. Cl. 341/22; 382/124

(57) ABSTRACT

Systems are provided that include an input device with a plurality of keys, at least one of the plurality of keys including a biometric sensor disposed therein. The system generally executes an application, receives input from a plurality of users using the input device, determines the identity of the user submitting the input, and attributes actual contribution in the application to the identified user.

This application claims priority to Provisional Application No. 61/024,415, filed Jan. 29, 2008, which is hereby incorporated by reference.

### BACKGROUND OF THE INVENTION

The present application relates to methods and systems for tracking user contribution to works in an electronic computing environment.

Various products are available that track changes to documents, such as the track changes features of Microsoft WORD and other word processing software. In these products, changes to a document are generally attributed to the user associated with the computing device at which the changes are being made. Although simple, actual contribution is not guaranteed. For example, a user may be working at a terminal associated with another user. In this instance, the document attributes the changes to the incorrect user. Accordingly, there is a need for methods and systems that track actual contribution to works.

### SUMMARY OF THE INVENTION

In one aspect of the methods and systems disclosed herein, a system is provided that includes an input device with a plurality of keys, at least one of the plurality of keys including a biometric sensor, a processor; and a memory, the memory comprising software that when executed causes the processor to perform a method. The method includes the steps of receiving login information from a first user; executing an application; receiving input from the first user with the input device; sampling biometric data with the biometric sensor associated with the at least one of the plurality of keys; determining an identity of the first user based on the biometric data sampled; attributing actual contribution in the application to the first user based on the input from the first user and the determined identity of the first user; receiving input from a second user with the input device; sampling biometric data with the biometric sensor associated with the at least one of the plurality of keys; determining an identity of the second user based on the biometric data sampled; and attributing actual contribution in the application to the second user based on the input from the second user and the determined identity of the second user.

In one embodiment, the input device includes an alphanumeric keyboard and wherein the biometric sensor is disposed in at least one of the alphanumeric keys.

In one embodiment, the biometric sensor includes a fingerprint reader.

In one embodiment, the alphanumeric key that includes the biometric sensor represents a letter when struck.

In one embodiment, the keyboard includes a plurality of alphanumeric keys each includes a biometric sensor.

In one embodiment, each of the alphanumeric keys represents a letter when struck.

In one embodiment, the processor samples biometric data when the letter is struck.

In one embodiment, the keyboard is a QWERTY keyboard and the biometric sensor is disposed in at least one of the a, s, d, f, j, k, l, and ; keys.

In one embodiment, the keyboard is a QWERTY keyboard and the biometric sensor is disposed in at least one of the a, e, i, o, and u keys.

In one embodiment, the processor samples biometric data periodically.

### BRIEF DESCRIPTION OF THE FIGURES

FIG. 1 illustrates a system according to at least one embodiment of the systems disclosed herein; and

FIG. 2 is a flowchart of a method according to at least one embodiment of the methods disclosed herein.

The following sections I-X provide a guide to interpreting the present application.

I. Terms

The term “product” means any machine, manufacture and/or composition of matter, unless expressly specified otherwise.

The term “process” means any process, algorithm, method or the like, unless expressly specified otherwise.

Each process (whether called a method, algorithm or otherwise) inherently includes one or more steps, and therefore all references to a “step” or “steps” of a process have an inherent antecedent basis in the mere recitation of the term ‘process’ or a like term. Accordingly, any reference in a claim to a ‘step’ or ‘steps’ of a process has sufficient antecedent basis.

The term “invention” and the like mean “the one or more inventions disclosed in this application”, unless expressly specified otherwise.

The terms “an embodiment”, “embodiment”, “embodiments”, “the embodiment”, “the embodiments”, “one or more embodiments”, “some embodiments”, “certain embodiments”, “one embodiment”, “another embodiment” and the like mean “one or more (but not all) embodiments of the disclosed invention(s)”, unless expressly specified otherwise.

The term “variation” of an invention means an embodiment of the invention, unless expressly specified otherwise.

A reference to “another embodiment” in describing an embodiment does not imply that the referenced embodiment is mutually exclusive with another embodiment (e.g., an embodiment described before the referenced embodiment), unless expressly specified otherwise.

The terms “including”, “comprising” and variations thereof mean “including but not limited to”, unless expressly specified otherwise.

The terms “a”, “an” and “the” mean “one or more”, unless expressly specified otherwise.

The term “plurality” means “two or more”, unless expressly specified otherwise. The term “herein” means “in the present application, including anything which may be incorporated by reference”, unless expressly specified otherwise.

The phrase “at least one of”, when such phrase modifies a plurality of things (such as an enumerated list of things) means any combination of one or more of those things, unless expressly specified otherwise. For example, the phrase “at least one of a widget, a car and a wheel” means either (i) a widget, (ii) a car, (iii) a wheel, (iv) a widget and a car, (v) a widget and a wheel, (vi) a car and a wheel, or (vii) a widget, a car and a wheel. The phrase “at least one of”, when such phrase modifies a plurality of things does not mean “one of each of” the plurality of things.

Numerical terms such as “one”, “two”, etc. when used as cardinal numbers to indicate quantity of something (e.g., one widget, two widgets), mean the quantity indicated by that numerical term, but do not mean at least the quantity indicated by that numerical term. For example, the phrase “one widget” does not mean “at least one widget”, and therefore the phrase “one widget” does not cover, e.g., two widgets.

The phrase “based on” does not mean “based only on”, unless expressly specified otherwise. In other words, the phrase “based on” describes both “based only on” and “based at least on”. The phrase “based at least on” is equivalent to the phrase “based at least in part on”.

The term “represent” and like terms are not exclusive, unless expressly specified otherwise. For example, the term “represents” does not mean “represents only”, unless expressly specified otherwise. In other words, the phrase “the data represents a credit card number” describes both “the data represents only a credit card number” and “the data represents a credit card number and the data also represents something else”.

The term “whereby” is used herein only to precede a clause or other set of words that express only the intended result, objective or consequence of something that is previously and explicitly recited. Thus, when the term “whereby” is used in a claim, the clause or other words that the term “whereby” modifies do not establish specific further limitations of the claim or otherwise restricts the meaning or scope of the claim.

The term “e.g.” and like terms mean “for example”, and thus does not limit the term or phrase it explains. For example, in the sentence “the computer sends data (e.g., instructions, a data structure) over the Internet”, the term “e.g.” explains that “instructions” are an example of “data” that the computer may send over the Internet, and also explains that “a data structure” is an example of “data” that the computer may send over the Internet. However, both “instructions” and “a data structure” are merely examples of “data”, and other things besides “instructions” and “a data structure” can be “data”.

The term “respective” and like terms mean “taken individually”. Thus if two or more things have “respective” characteristics, then each such thing has its own characteristic, and these characteristics can be different from each other but need not be. For example, the phrase “each of two machines has a respective function” means that the first such machine has a function and the second such machine has a function as well. The function of the first machine may or may not be the same as the function of the second machine.

The term “i.e.” and like terms mean “that is”, and thus limits the term or phrase it explains. For example, in the sentence “the computer sends data (i.e., instructions) over the Internet”, the term “i.e.” explains that “instructions” are the “data” that the computer sends over the Internet.

Any given numerical range shall include whole and fractions of numbers within the range. For example, the range “1 to 10” shall be interpreted to specifically include whole numbers between 1 and 10 (e.g., 1, 2, 3, 4, . . . 9) and non-whole numbers (e.g., 1.1, 1.2, . . . 1.9).

Where two or more terms or phrases are synonymous (e.g., because of an explicit statement that the terms or phrases are synonymous), instances of one such term/phrase does not mean instances of another such term/phrase must have a different meaning. For example, where a statement renders the meaning of “including” to be synonymous with “including but not limited to”, the mere usage of the phrase “including but not limited to” does not mean that the term “including” means something other than “including but not limited to”.

II. Determining

The term “determining” and grammatical variants thereof (e.g., to determine a price, determining a value, determine an object which meets a certain criterion) is used in an extremely broad sense. The term “determining” encompasses a wide variety of actions and therefore “determining” can include calculating, computing, processing, deriving, investigating, looking up (e.g., looking up in a table, a database or another data structure), ascertaining and the like. Also, “determining” can include receiving (e.g., receiving information), accessing (e.g., accessing data in a memory) and the like. Also, “determining” can include resolving, selecting, choosing, establishing, and the like.

The term “determining” does not imply certainty or absolute precision, and therefore “determining” can include estimating, extrapolating, predicting, guessing and the like.

The term “determining” does not imply that mathematical processing must be performed, and does not imply that numerical methods must be used, and does not imply that an algorithm or process is used.

The term “determining” does not imply that any particular device must be used. For example, a computer need not necessarily perform the determining.

III. Forms of Sentences

Where a limitation of a first claim would cover one of a feature as well as more than one of a feature (e.g., a limitation such as “at least one widget” covers one widget as well as more than one widget), and where in a second claim that depends on the first claim, the second claim uses a definite article “the” to refer to the limitation (e.g., “the widget”), this does not imply that the first claim covers only one of the feature, and this does not imply that the second claim covers only one of the feature (e.g., “the widget” can cover both one widget and more than one widget).

When an ordinal number (such as “first”, “second”, “third” and so on) is used as an adjective before a term, that ordinal number is used (unless expressly specified otherwise) merely to indicate a particular feature, such as to distinguish that particular feature from another feature that is described by the same term or by a similar term. For example, a “first widget” may be so named merely to distinguish it from, e.g., a “second widget”. Thus, the mere usage of the ordinal numbers “first” and “second” before the term “widget” does not indicate any other relationship between the two widgets, and likewise does not indicate any other characteristics of either or both widgets. For example, the mere usage of the ordinal numbers “first” and “second” before the term “widget” (1) does not indicate that either widget comes before or after any other in order or location; (2) does not indicate that either widget occurs or acts before or after any other in time; and (3) does not indicate that either widget ranks above or below any other, as in importance or quality. In addition, the mere usage of ordinal numbers does not define a numerical limit to the features identified with the ordinal numbers. For example, the mere usage of the ordinal numbers “first” and “second” before the term “widget” does not indicate that there must be no more than two widgets.

When a single device, article or other product is described herein, more than one device/article (whether or not they cooperate) may alternatively be used in place of the single device/article that is described. Accordingly, the functionality that is described as being possessed by a device may alternatively be possessed by more than one device/article (whether or not they cooperate).

Similarly, where more than one device, article or other product is described herein (whether or not they cooperate), a single device/article may alternatively be used in place of the more than one device or article that is described. For example, a plurality of computer-based devices may be substituted with a single computer-based device. Accordingly, the various functionality that is described as being possessed by more than one device or article may alternatively be possessed by a single device/article.

The functionality and/or the features of a single device that is described may be alternatively embodied by one or more other devices which are described but are not explicitly described as having such functionality/features. Thus, other embodiments need not include the described device itself, but rather can include the one or more other devices which would, in those other embodiments, have such functionality/features.

IV. Disclosed Examples and Terminology are not Limiting

Neither the Title (set forth at the beginning of the first page of the present application) nor the Abstract (set forth at the end of the present application) is to be taken as limiting in any way as the scope of the disclosed invention(s), is to be used in interpreting the meaning of any claim or is to be used in limiting the scope of any claim.. An Abstract has been included in this application merely because an Abstract is required under 37 C.F.R. §1.72(b).

The title of the present application and headings of sections provided in the present application are for convenience only, and are not to be taken as limiting the disclosure in any way.

Numerous embodiments are described in the present application, and are presented for illustrative purposes only. The described embodiments are not, and are not intended to be, limiting in any sense. The presently disclosed invention(s) are widely applicable to numerous embodiments, as is readily apparent from the disclosure. One of ordinary skill in the art will recognize that the disclosed invention(s) may be practiced with various modifications and alterations, such as structural, logical, software, and electrical modifications. Although particular features of the disclosed invention(s) may be described with reference to one or more particular embodiments and/or drawings, it should be understood that such features are not limited to usage in the one or more particular embodiments or drawings with reference to which they are described, unless expressly specified otherwise.

Though an embodiment may be disclosed as including several features, other embodiments of the invention may include fewer than all such features. Thus, for example, a claim may be directed to less than the entire set of features in a disclosed embodiment, and such claim would not include features beyond those features that the claim expressly recites.

No embodiment of method steps or product elements described in the present application constitutes the invention claimed herein, or is essential to the invention claimed herein, or is coextensive with the invention claimed herein, except where it is either expressly stated to be so in this specification or expressly recited in a claim.

The preambles of the claims that follow recite purposes, benefits and possible uses of the claimed invention only and do not limit the claimed invention.

The present disclosure is not a literal description of all embodiments of the invention(s). Also, the present disclosure is not a listing of features of the invention(s) which must be present in all embodiments.

All disclosed embodiment are not necessarily covered by the claims (even including all pending, amended, issued and canceled claims). In addition, an embodiment may be (but need not necessarily be) covered by several claims. Accordingly, where a claim (regardless of whether pending, amended, issued or canceled) is directed to a particular embodiment, such is not evidence that the scope of other claims do not also cover that embodiment.

Devices that are described as in communication with each other need not be in continuous communication with each other, unless expressly specified otherwise. On the contrary, such devices need only transmit to each other as necessary or desirable, and may actually refrain from exchanging data most of the time. For example, a machine in communication with another machine via the Internet may not transmit data to the other machine for long period of time (e.g. weeks at a time). In addition, devices that are in communication with each other may communicate directly or indirectly through one or more intermediaries.

A description of an embodiment with several components or features does not imply that all or even any of such components/features are required. On the contrary, a variety of optional components are described to illustrate the wide variety of possible embodiments of the present invention(s). Unless otherwise specified explicitly, no component/feature is essential or required.

Although process steps, algorithms or the like may be described or claimed in a particular sequential order, such processes may be configured to work in different orders. In other words, any sequence or order of steps that may be explicitly described or claimed does not necessarily indicate a requirement that the steps be performed in that order. The steps of processes described herein may be performed in any order possible. Further, some steps may be performed simultaneously despite being described or implied as occurring non-simultaneously (e.g., because one step is described after the other step). Moreover, the illustration of a process by its depiction in a drawing does not imply that the illustrated process is exclusive of other variations and modifications thereto, does not imply that the illustrated process or any of its steps are necessary to the invention(s), and does not imply that the illustrated process is preferred.

Although a process may be described as including a plurality of steps, that does not imply that all or any of the steps are preferred, essential or required. Various other embodiments within the scope of the described invention(s) include other processes that omit some or all of the described steps. Unless otherwise specified explicitly, no step is essential or required.

Although a process may be described singly or without reference to other products or methods, in an embodiment the process may interact with other products or methods. For example, such interaction may include linking one business model to another business model. Such interaction may be provided to enhance the flexibility or desirability of the process.

Although a product may be described as including a plurality of components, aspects, qualities, characteristics and/or features, that does not indicate that any or all of the plurality are preferred, essential or required. Various other embodiments within the scope of the described invention(s) include other products that omit some or all of the described plurality.

An enumerated list of items (which may or may not be numbered) does not imply that any or all of the items are mutually exclusive, unless expressly specified otherwise. Likewise, an enumerated list of items (which may or may not be numbered) does not imply that any or all of the items are comprehensive of any category, unless expressly specified otherwise. For example, the enumerated list “a computer, a laptop, a PDA” does not imply that any or all of the three items of that list are mutually exclusive and does not imply that any or all of the three items of that list are comprehensive of any category.

An enumerated list of items (which may or may not be numbered) does not imply that any or all of the items are equivalent to each other or readily substituted for each other.

All embodiments are illustrative, and do not imply that the invention or any embodiments were made or performed, as the case may be.

V. Computing

It will be readily apparent to one of ordinary skill in the art that the various processes described herein may be implemented by, e.g., appropriately programmed general purpose computers, special purpose computers and computing devices. Typically a processor (e.g., one or more microprocessors, one or more microcontrollers, one or more digital signal processors) will receive instructions (e.g., from a memory or like device), and execute those instructions, thereby performing one or more processes defined by those instructions. Instructions may be embodied in, e.g., one or more computer programs, one or more scripts.

A “processor” means one or more microprocessors, central processing units (CPUs), computing devices, microcontrollers, digital signal processors, or like devices or any combination thereof, regardless of the architecture (e.g., chip-level multiprocessing/multi-core, RISC, CISC, Microprocessor without Interlocked Pipeline Stages, pipelining configuration, simultaneous multithreading).

Thus a description of a process is likewise a description of an apparatus for performing the process. The apparatus that performs the process can include, e.g., a processor and those input devices and output devices that are appropriate to perform the process.

Further, programs that implement such methods (as well as other types of data) may be stored and transmitted using a variety of media (e.g., computer readable media) in a number of manners. In some embodiments, hard-wired circuitry or custom hardware may be used in place of, or in combination with, some or all of the software instructions that can implement the processes of various embodiments. Thus, various combinations of hardware and software may be used instead of software only.

The term “computer-readable medium” refers to any medium, a plurality of the same, or a combination of different media, that participate in providing data (e.g., instructions, data structures) which may be read by a computer, a processor or a like device. Such a medium may take many forms, including but not limited to, non-volatile media, volatile media, and transmission media. Non-volatile media include, for example, optical or magnetic disks and other persistent memory. Volatile media include dynamic random access memory (DRAM), which typically constitutes the main memory. Transmission media include coaxial cables, copper wire and fiber optics, including the wires that comprise a system bus coupled to the processor. Transmission media may include or convey acoustic waves, light waves and electromagnetic emissions, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, an EPROM, a FLASH-EEPROM, any other memory chip or cartridge, a carrier wave as described hereinafter, or any other medium from which a computer can read.

Various forms of computer readable media may be involved in carrying data (e.g. sequences of instructions) to a processor. For example, data may be (i) delivered from RAM to a processor; (ii) carried over a wireless transmission medium; (iii) formatted and/or transmitted according to numerous formats, standards or protocols, such as Ethernet (or IEEE 802.3), SAP, ATP, Bluetooth™, and TCP/IP, TDMA, CDMA, and 3G; and/or (iv) encrypted to ensure privacy or prevent fraud in any of a variety of ways well known in the art.

Thus a description of a process is likewise a description of a computer-readable medium storing a program for performing the process. The computer-readable medium can store (in any appropriate format) those program elements which are appropriate to perform the method.

Just as the description of various steps in a process does not indicate that all the described steps are required, embodiments of an apparatus include a computer/computing device operable to perform some (but not necessarily all) of the described process.

Likewise, just as the description of various steps in a process does not indicate that all the described steps are required, embodiments of a computer-readable medium storing a program or data structure include a computer-readable medium storing a program that, when executed, can cause a processor to perform some (but not necessarily all) of the described process.

Where databases are described, it will be understood by one of ordinary skill in the art that (i) alternative database structures to those described may be readily employed, and (ii) other memory structures besides databases may be readily employed. Any illustrations or descriptions of any sample databases presented herein are illustrative arrangements for stored representations of information. Any number of other arrangements may be employed besides those suggested by, e.g., tables illustrated in drawings or elsewhere. Similarly, any illustrated entries of the databases represent exemplary information only; one of ordinary skill in the art will understand that the number and content of the entries can be different from those described herein. Further, despite any depiction of the databases as tables, other formats (including relational databases, object-based models and/or distributed databases) could be used to store and manipulate the data types described herein. Likewise, object methods or behaviors of a database can be used to implement various processes, such as the described herein. In addition, the databases may, in a known manner, be stored locally or remotely from a device which accesses data in such a database.

Various embodiments can be configured to work in a network environment including a computer that is in communication (e.g., via a communications network) with one or more devices. The computer may communicate with the devices directly or indirectly, via any wired or wireless medium (e.g. the Internet, LAN, WAN or Ethernet, Token Ring, a telephone line, a cable line, a radio channel, an optical communications line, commercial on-line service providers, bulletin board systems, a satellite communications link, a combination of any of the above). Each of the devices may themselves comprise computers or other computing devices, such as those based on the Intel® Pentium® or Centrino™ processor, that are adapted to communicate with the computer. Any number and type of devices may be in communication with the computer.

In an embodiment, a server computer or centralized authority may not be necessary or desirable. For example, the present invention may, in an embodiment, be practiced on one or more devices without a central authority. In such an embodiment, any functions described herein as performed by the server computer or data described as stored on the server computer may instead be performed by or stored on one or more such devices.

Where a process is described, in an embodiment the process may operate without any user intervention. In another embodiment, the process includes some human intervention (e.g., a step is performed by or with the assistance of a human).

VI. Continuing Applications

The present disclosure provides, to one of ordinary skill in the art, an enabling description of several embodiments and/or inventions. Some of these embodiments and/or inventions may not be claimed in the present application, but may nevertheless be claimed in one or more continuing applications that claim the benefit of priority of the present application.

Applicants intend to file additional applications to pursue patents for subject matter that has been disclosed and enabled but not claimed in the present application.

VII. 35 U.S.C. §112 paragraph 6

In a claim, a limitation of the claim which includes the phrase “means for” or the phrase “step for” means that 35 U.S.C. §112, paragraph 6, applies to that limitation.

In a claim, a limitation of the claim which does not include the phrase “means for” or the phrase “step for” means that 35 U.S.C. §112, paragraph 6 does not apply to that limitation, regardless of whether that limitation recites a function without recitation of structure, material or acts for performing that function. For example, in a claim, the mere use of the phrase “step of” or the phrase “steps of” in referring to one or more steps of the claim or of another claim does not mean that 35 U.S.C. §112, paragraph 6, applies to that step(s).

With respect to a means or a step for performing a specified function in accordance with 35 U.S.C. §112, paragraph 6, the corresponding structure, material or acts described in the specification, and equivalents thereof, may perform additional functions as well as the specified function.

Computers, processors, computing devices and like products are structures that can perform a wide variety of functions. Such products can be operable to perform a specified function by executing one or more programs, such as a program stored in a memory device of that product or in a memory device which that product accesses. Unless expressly specified otherwise, such a program need not be based on any particular algorithm, such as any particular algorithm that might be disclosed in the present application. It is well known to one of ordinary skill in the art that a specified function may be implemented via different algorithms, and any of a number of different algorithms would be a mere design choice for carrying out the specified function.

Therefore, with respect to a means or a step for performing a specified function in accordance with 35 U.S.C. §112, paragraph 6, structure corresponding to a specified function includes any product programmed to perform the specified function. Such structure includes programmed products which perform the function, regardless of whether such product is programmed with (i) a disclosed algorithm for performing the function, (ii) an algorithm that is similar to a disclosed algorithm, or (iii) a different algorithm for performing the function.

Where there is recited a means for performing a function that is a method, one structure for performing this method includes a computing device (e.g., a general purpose computer) that is programmed and/or configured with appropriate hardware to perform that function.

Also included is a computing device (e.g., a general purpose computer) that is programmed and/or configured with appropriate hardware to perform that function via other algorithms as would be understood by one of ordinary skill in the art.

VIII. Disclaimer

Numerous references to a particular embodiment do not indicate a disclaimer or disavowal of additional, different embodiments, and similarly references to the description of embodiments which all include a particular feature do not indicate a disclaimer or disavowal of embodiments which do not include that particular feature. A clear disclaimer or disavowal in the present application shall be prefaced by the phrase “does not include” or by the phrase “cannot perform”.

IX. Incorporation By Reference

Any patent, patent application or other document referred to herein is incorporated by reference into this patent application as part of the present disclosure, but only for purposes of written description and enablement in accordance with 35 U.S.C. §112, paragraph 1, and should in no way be used to limit, define, or otherwise construe any term of the present application, unless without such incorporation by reference, no ordinary meaning would have been ascertainable by a person of ordinary skill in the art. Such person of ordinary skill in the art need not have been in any way limited by any embodiments provided in the reference

Any incorporation by reference does not, in and of itself, imply any endorsement of, ratification of or acquiescence in any statements, opinions, arguments or characterizations contained in any incorporated patent, patent application or other document, unless explicitly specified otherwise in this patent application.

X. Prosecution History

In interpreting the present application (which includes the claims), one of ordinary skill in the art shall refer to the prosecution history of the present application, but not to the prosecution history of any other patent or patent application, regardless of whether there are other patent applications that are considered related to the present application, and regardless of whether there are other patent applications that share a claim of priority with the present application.

### DETAILED DESCRIPTION OF THE INVENTION

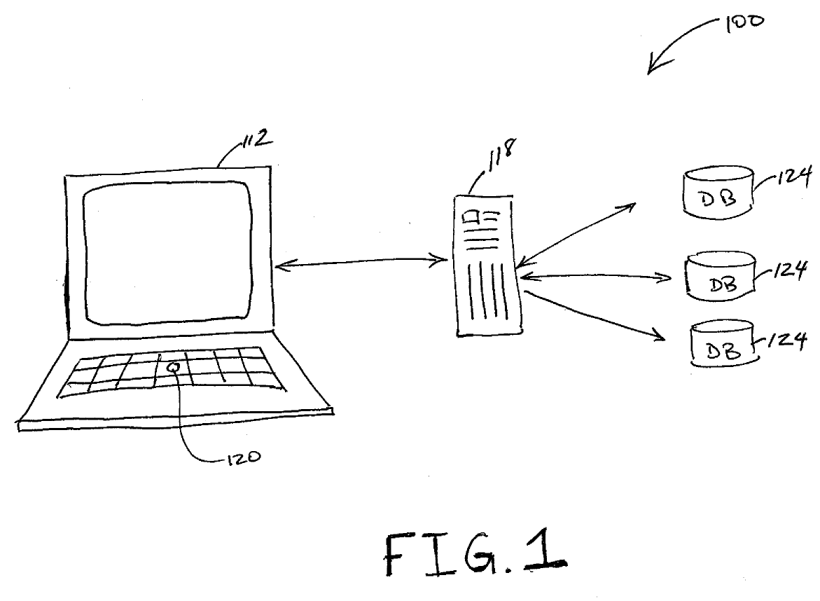

Referring to FIG. 1, a system 100 according to at least one embodiment of the systems disclosed herein includes at least one computing device, such as a remote computer 118, e.g., a server computer, a client device 112, or a combination thereof The computing device generally includes at least one processor, and a memory, such as ROM, RAM, FLASH, etc., or any computer readable medium, such as a hard drive, a flash-drive, an optical or magnetic disk, etc. The memory or computer readable medium preferably includes software stored thereon that when executed performs one or more steps of the methods disclosed herein, including communicating data back and forth between devices, displaying interface screens, etc. The computing device may also be associated with or have access to one or more databases 124 for retrieving and storing the various types of data discussed herein, including identity verification data, such as an ID and password, biometric data, etc.

In one embodiment, the system 100 includes a plurality of computing devices, such as a remote computer 118 coupled to at least one client device 112 over a communication network 116, which are generally configured or otherwise capable of transmitting and/or receiving communications to and/or from each other. The term remote in this context merely means that the remote computer 118 and the client device are separate from each other. Thus, the devices may be remote even if the devices are located within the same room. As such, the client device 112 is preferably configured or otherwise capable of transmitting and/or receiving communications to and/or from the remote computer 1 18. This may be accomplished with a communication element 124, such as a modem, an Ethernet interface, a transmitter/receiver, etc., that enables communication with a similarly equipped remote computer 118, wirelessly, wired, or a combination thereof It is understood that the relative functionality described herein may be provided by the remote computer 118, by the client device 112, or both, and is thus not limited to any one implementation discussed herein.

The client devices 112 may include, without limitation, a mobile phone, PDA, pocket PC, personal computer, as well as any special or general purpose client device, such as a slot machine, a video poker machine, video or computer-based versions of table games, e.g., roulette, blackjack, etc. As such, the client device 112 preferably includes a processor, a memory, a display, such as a CRT or an LCD monitor, for displaying information and/or graphics associated with the services provided by the system 100, and at least one input device, such as a mouse, a touch-sensitive pad, a pointer, a stylus, a trackball, a button, e.g., alphanumeric, a scroll wheel, a touch-sensitive monitor, etc., or a combination thereof, for users to enter commands and/or information relevant to the system services.

In at least one embodiment, the client device 112 includes or is otherwise associated with at least one biometric sensor 120. The biometric sensor 120 is any device that is used to determine directly from the user at least one item of biometric data associated with a user, such as a fingerprint reader, an iris scanner, a retinal scanner, a vascular pattern reader, a facial recognition camera, etc. The biometric sensor 120 may be embodied in hardware, software, or a combination thereof. The biometric sensor 120 may further share resources with other components of the client device 112, such as the processor, memory, a camera, a microphone, a speaker, etc. The biometric data is generally obtained with the biometric sensor 120 and used at least to verify the identity of the user as discussed herein. In this regard, biometric data may be compared with previously obtained/stored physical biometric data that has preferably been authenticated as being associated with a particular authorized user, and access to the gaming system's services may be provided based on a positive match thereof.

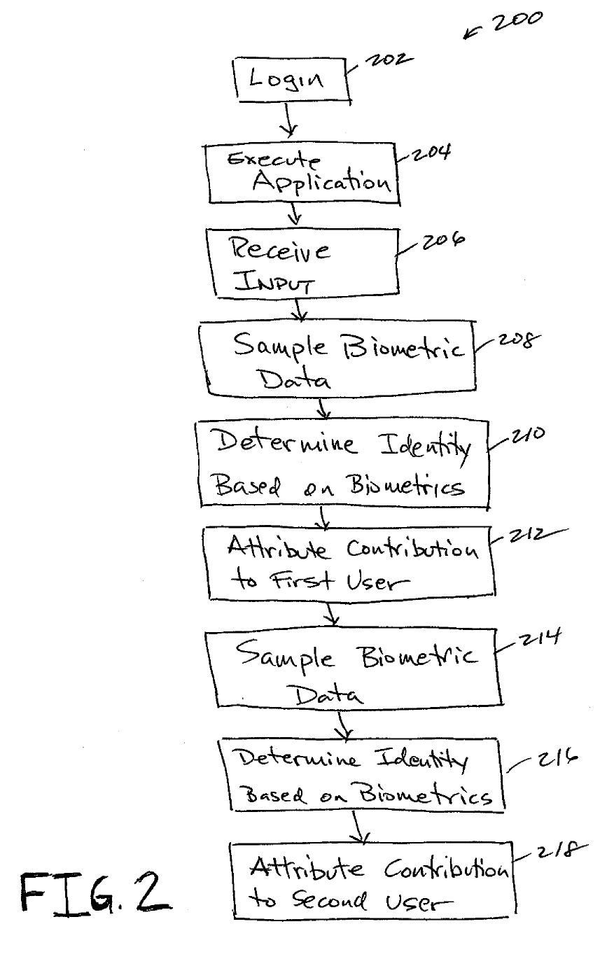

Referring to FIG. 2, in at least embodiment, the system 100, e.g., the client device 112, server 118, or a combination thereof, generally tracks an individual's actual contribution to a work and may thereafter react appropriately. The reaction is generally dependent on the context of the tracking. For example, in the context of a written work prepared, e.g., with a word processing program, the system 100 may simply track the actual contribution to the written work and highlight the contribution in the document. In another context, such as in a gaming environment, the system may prompt the user to confirm his or her identity and/or block access to the game.

In at least one embodiment, the method begins at 202 with a first user logging into the computing device and at 204 executing an application that incorporates the actual contribution tracking features discussed herein. At 206, the computing device receives input from the first user. At 208, the system 100 thereafter or concurrently with the input received samples biometrics of the first user and at 210 determines the identity of the first user based on the biometrics. At 210, the system 100 attributes contribution at 212 to the first user independent of login. The system 100 repeats the sampling and attribution steps at 214-218, except that contribution is attributed to a second user. This may occur, for example, when the second user makes changes using the computing device during the login session of the first user.

Actual contribution may be determined in a variety of ways. In one embodiment, actual contribution is accomplished with biometric sampling during contribution to the work. For example, biometric or other recognition of clerical or administrative contribution may be determined by embedding or otherwise associating the identity of the typist in, with, or as letters are typed at a keyboard, or with any other similar application of recorded manual input. In various embodiments, the system 100 includes a keyboard or other input means with a plurality of keys or buttons that each include a camera or other biometric element 120, such as a CCD or other solid state camera, possibly a nano-size camera, fingerprint sensor, and/or fiber-optic or other link to a central image recorder. In this instance, at least a portion of the fingerprint of the typing finger or fingers for some or each keystroke may be registered with or as the user depresses the key or button. Alternatively or additionally, biometrics may be sampled, e.g., periodically, whenever the biometric sample is available, such as when the user rests his hand on the key.

The biometric element 120 may be disposed on fewer than all of the keys, such as the most commonly used keys. In a QWERTY keyboard, the biometric element may be disposed on/in some or all of the resting keys, e.g., a, s, d, f, j, k, l, and ;. In this instance, biometric sampling may be taken as the user rests his fingers on the resting keys and/or as certain keys are depressed. Similarly, the biometric element may be disposed on commonly struck keys, such as vowels, e.g., a, e, i, o, u.

The fingerprint or other biometric sample may be correlated to previously recorded biometrics and may be neutral as to the key pressed. Rather than monitoring typing technique, wherein certain fingers are required to strike certain keys, the biometric element on the key may record and register all or some down strokes and check or test for repetition of fingerprint patterns. For example, biometric samples for a sequence of keystrokes, such as when spelling a certain word, may be compared with previously stored biometric sampling sequences. In this way it may be verified that the characters have been input by the biometrically identified user, and not another party who may have access to certain login information, and may separately permit or prohibit and simultaneously identify when there has been a change of biological users. User continuity may similarly be verified without reference to any specific individual. In this instance, the comparison will be accomplished with reference to a string of previous reading therewith determining if there is a break or change in the string of readings. Rather than just taking a single biometric reading at the start of a session, the system may further take continual or periodic (e.g. every 1, 2, seconds, minutes, hours, etc.) biometric readings with each action or each periodic interval.

The continuation of a work attributed to a particular user based on actual keystrokes may be stored with the file that represents the work, e.g. in metadata associated therewith, in a separate file, or both. Continuation data may be encrypted to prevent any unwanted tampering with the data.

It is understood that the inventions disclosed herein may be used with various other biometric data including individual voltage registers, heat signatures, etc., although examples herein utilize fingerprints, and are therefore not limited thereto.

The techniques disclosed herein may be used to verify that original works are by their creators, i.e. that students have typed their own papers, and can also be used as an additional measure in combination with software designed to identify instances of plagiarism. For example, where a student obtained a prior written work and retyped it, the combination of anti-plagiarism software and the font or key biometrics would permit it to be determined that the individual student had indeed typed the passages that plagiarize the work of others, or, where elements previously produced utilizing the font or key biometric technology are otherwise incorporated into a work created substantially by the student, to identify those portions of the work that were created by others.

In various embodiments, the font or key biometric data may facilitate appropriate use of works either through quotation or reference, by furnishing the requisite data to enable footnoting and credit attribution for both published and non-published works. This may have numerous benefits with respect to the sharing of information, including the protection of secure information, the traceability of source information, through increasing the confidence of creators of intellectual property to digitize their information by embedding their creative ownership within such information, and though the facilitation of shares of fractional portions of a digitized work through the encoding of intellectual property elements within each fractional aspect of the whole.

In various embodiments the font or key biometric data may also be utilized for non textual works in their digitization, either through the encoding of digital elements of imagery, or through the application of the key biometric technology in the creation of musical or other audio works accomplished by qwerty keyboard, piano keyboard, or any alternative musical instrument where the sampling of biometrics may be accomplished through the sampling of the creator's biometrics via the touch input of creative components, as described herein.

In various embodiments, font or keystroke biometrics may be employed in a gaming environment where, for example, the identity of a user within a game may be continually verified and checked during play. In various embodiments this may permit continual or periodic verification that the user is not prohibited from participating in the game, i.e. is over 18 years old where this is required, or that the gaming participant is the same gaming participant who began the game, where continuity of the same participant is required, such as in gaming situations where handicapping of players according to ability is a component of the gaming environment.

In various embodiments, the font or key biometrics may be used to determine and to verify the contribution of clerical or administrative personnel to a large effort, where in the past the creative contributions only could be checked.

In broader applications, the font or key biometrics may be used to track who originated any passages or data in a digital environment, and may be assigned to individual PCs as well, i.e. to record repetitive keyboard and PC combinations, permitting unsigned text to be traced to a particular machine. This may be accomplished in the context of a digital signature that includes a series of biometric readings each associated with the corresponding key struck by the originator. For example, the digital signature for John Doe, may be the series of biometric readings with each of the keys struck: J, o, h, n, _, D, o, and e. In instances where fewer than all of the keys include the biometric element, such as on the resting keys only, the series of biometric readings will be: J, h, and D.

In various embodiments there will be a facility to perform a biometrics check to reveal whether any character in a document has been tampered with under any circumstances, whether without the creator's knowledge, with appropriation from other documents, or being passed off as a work by an author different than the creator.

In various embodiments, font and keystroke biometrics may also be employed in encrypted and non-encrypted security applications such as that the originators of electronic actions, instructions, or messages may be tracked and recorded for later discovery. In such security application there may be privacy encryption keys imposed in hierarchical levels allocated to private users, commercial users, and security or intelligence users. In various embodiments such encoding may be used to declassify data or to restrict classified data from being distributed to unauthorized personnel.

In various embodiments the font biometrics technology may be applied to interfaces where the input interface is a touch sensitive screen. In various embodiments that touch screen may register an entire fingerprint or any portion thereof from the surface layer where the touch is applied. In various embodiments the touch screen may correlate individual voltage or resistance signatures to the input actions. In such cases the correlation is between the discrete input action or periodic interval and the selected or available biometric signature. In various embodiments the touch screen may measure some portion of biological residue, or a wave pattern that results from the propagation of electromagnetic impulses through the biological residue.

While the foregoing invention has been described in some detail for purposes of clarity and understanding, it will be appreciated by one skilled in the art that, from a reading of the disclosure, various changes in form and detail can be made without departing from the true scope of the invention.

What is claimed is:

1. A system comprising:
an input device comprising a plurality of keys, at least one of the plurality of keys comprising a biometric sensor;
a processor; and
a memory, the memory comprising software that when executed causes the processor to perform a method comprising:
receiving login information from a first user;
executing an application;
receiving input from the first user with the input device;
sampling biometric data with the biometric sensor associated with the at least one of the plurality of keys;
determining an identity of the first user based on the biometric data sampled;
attributing actual contribution in the application to the first user based on the input from the first user and the determined identity of the first user;
receiving input from a second user with the input device;
sampling biometric data with the biometric sensor associated with the at least one of the plurality of keys;
determining an identity of the second user based on the biometric data sampled; and
attributing actual contribution in the application to the second user based on the input from the second user and the determined identity of the second user.

2. The system of claim 1, wherein the input device comprises an alphanumeric keyboard and wherein the biometric sensor is disposed in at least one of the alphanumeric keys.

3. The system of claim 2, wherein biometric sensor comprises a fingerprint reader.

4. The system of claim 2, wherein the alphanumeric key comprising the biometric sensor represents a letter when struck.

5. The system of claim 4, wherein the keyboard comprises a plurality of alphanumeric keys each comprising a biometric sensor.

6. The system of claim 5, wherein each of the alphanumeric keys represents a letter when struck.

7. The system of claim 4, wherein the processor samples biometric data when the letter is struck.

8. The system of claim 4, wherein the keyboard comprises a QWERTY keyboard and wherein the biometric sensor is disposed in at least one of the a, s, d, f,j, k, l, and; keys.

9. The system of claim 4, wherein the keyboard comprises a QWERTY keyboard and wherein the biometric sensor is disposed in at least one of the a, e, i, o, and u keys.

10. The system of claim 4, wherein the processor samples biometric data periodically.
